(19) United States
(12) Patent Application Publication
(10) Pub. No.: US 2013/0027714 A1
(43) Pub. Date: Jan. 31, 2013

(54) LIGHT SOURCE DEVICE AND OPTICAL COHERENCE TOMOGRAPHY APPARATUS

(71) Applicants: Minoru Yoshii, Tokyo (JP); Eiichi Fujii, Kamakura-shi (JP)

(72) Inventors: Minoru Yoshii, Tokyo (JP); Eiichi Fujii, Kamakura-shi (JP)

(73) Assignee: CANON KABUSHIKI KAISHA, Tokyo (JP)

(21) Appl. No.: 13/554,800

(22) Filed: Jul. 20, 2012

(30) Foreign Application Priority Data
Jul. 25, 2011 (JP) 2011-162158

(51) Int. Cl. G01B 9/02; H01S 5/00; H01S 3/10

(52) U.S. Cl. 356/497; 359/333; 359/344

(57) ABSTRACT

A light source device capable of varying a light oscillation wavelength includes a plurality of optical gain media, a dispersing element, and a wavelength selecting element. The optical gain media amplify light, and have gain wavelength bands that partially overlap and different maximum gain wavelengths. The dispersing element is formed of a single element. Each of light beams emitted from the optical gain media is incident on the dispersing element. The dispersing element disperses the light beams emitted from the optical gain media into light beams of different wavelengths. The wavelength selecting element selects a light beam of a predetermined wavelength from the light beams of different wavelengths into which the light beams emitted from the optical gain media are dispersed by the dispersing element. The light source device emits the light beam of the predetermined wavelength selected by the wavelength selecting element.

### BACKGROUND OF THE INVENTION

1. Field of the Invention

The present invention relates to a light source device capable of varying an oscillation wavelength and an optical coherence tomography apparatus.

2. Description of the Related Art

Various light sources, in particular, laser light sources, capable of varying an oscillation wavelength have been used in the field of communication networks and inspection apparatuses. The oscillation wavelength is the wavelength that is resonating in a cavity.

High-speed wavelength switching is required in the field of communication network, and high-speed and wide-range wavelength sweeping is required in the field of inspection apparatuses.

With regard to inspection apparatuses, wavelength-varying or wavelength-sweeping light sources are used in, for example, laser spectroscopes, dispersion measuring devices, film-thickness measuring devices, or swept source optical coherence tomography (OCT) apparatuses.

OCT apparatuses capture tomographic images of an inspection object by using interference of low coherence light. This imaging technology provides a spatial resolution in the order of microns and is not invasive, and therefore has been widely researched in the medical field.

OCT apparatuses have a resolution of several micrometers in the depth direction, and are capable of capturing tomographic images at a depth of several millimeters. An OCT apparatus is used in, for example, ophthalmic imaging or dental imaging.

A swept-source OCT (SS-OCT) apparatus includes a light source whose oscillation wavelength (frequency) is temporally swept, and is an example of a Fourier domain OCT (FD-OCT).

While a spectral domain OCT (SD-OCT), which is also an example of an FD-OCT, requires a spectroscope for obtaining a spectrum of interference light, no spectroscope is used in the SS-OCT. Therefore, loss in the amount of light is small and high-S/N-ratio imaging can be expected.

In the case where a wavelength-sweeping light source is used in a medical imaging apparatus, an image capturing time can be reduced by increasing the sweeping speed. The wavelength-sweeping light source is suitable for, for example, so-called in situ-in vivo imaging in which a body tissue is observed without taking it out from a living body.

U.S. Pat. No. 7,142,569 (hereinafter referred to as Patent Literature 1) describes an example of a wavelength-varying light source device which includes an optical amplifying medium and a reflector including a diffraction grating disposed outside the optical amplifying medium.

FIG. 22 illustrates the light source device described in Patent Literature 1.

Referring to FIG. 22, an optical amplifying medium 2212 has a function of generating original light and a function of amplifying the generated light.

An end surface of the optical amplifying medium 2212 that is closer to a diffraction grating 2216 is coated with an antireflection film. The other end surface is coated with a highly reflective film.

A collimator lens 2214 collimates divergent light emitted from an emission end surface, which is the end surface coated with the antireflection film, of the optical amplifying medium 2212. A condensing lens 2218 causes the collimated light to converge. Reference numeral 2220 denotes a wavelength selecting unit.

The wavelength selecting unit 2220 includes a mirror 2224, a light blocking member 2222 having a slit-shaped opening 2222a, and a mechanism that moves the slit-shaped opening 2222a in the direction shown by the arrow.

In the light source device illustrated in FIG. 22, the mirror 2224 in the wavelength selecting unit 2220 and an end surface of the optical amplifying medium 2212 form an optical resonator, and light having the same wavelength as that of the light beam selected by the slit-shaped opening 2222a is emitted from the end surface of the optical amplifying medium 2212.

U.S. Pat. No. 7,519,096 (hereinafter referred to as Patent Literature 2) describes an example of a wavelength-varying light source device which includes a wavelength selecting unit including a rotating disc. FIG. 23 illustrates the light source device described in Patent Literature 2.

Referring to FIG. 23, an optical fiber waveguide 2301 guides light from an optical amplifying medium (not shown) having an outer end surface coated with a highly reflective film. A collimator lens 2302 collimates divergent light 2330 emitted from an end of the optical fiber waveguide 2301.

A diffraction grating 2316 diffracts the light into beams of different wavelengths. A condensing lens 2350 causes the diffracted light beams to converge. A rotating disc 2310 has a wavelength selecting function, and a plurality of strip-shaped portions (slit) 2312 are radially arranged on the rotating disc 2310.

The strip-shaped portions 2312 have reflective surfaces, and the rotating disc 2310 has an antireflective surface in areas other than the strip-shaped portions 2312.

In this device, the diffraction grating 2316 angularly disperses the divergent light 2330, which is generated by the optical amplifying medium (not shown), into beams of different wavelengths λ1 to λn. Then, the condensing lens 2350 causes the diffracted light beams to converge on the rotating disc 2310 in the wavelength selecting unit.

The rotating disc 2310 rotates so as to select a light beam of desired wavelength λ. Accordingly, the outer end surface of the optical amplifying medium (not shown) and one of the strip-shaped portions 2312 form an optical resonator in which laser oscillation occurs at wavelength λ.

In the devices described in Patent Literatures 1 and 2, the wavelength range of light that can be output as laser light is determined by the gain band of the optical amplifying medium (optical gain medium). Therefore, the wavelength range may not be sufficient in the case where laser oscillation over a wide wavelength band is required.

The present invention provides a wavelength-sweeping light source device capable of causing stable oscillation over a wide wavelength band.

### SUMMARY OF THE INVENTION

A light source device capable of varying a light oscillation wavelength includes a plurality of optical gain media, a dispersing element, and a wavelength selecting element. The optical gain media amplify light, and have gain wavelength bands that partially overlap and different maximum gain wavelengths. The dispersing element is formed of a single element. Each of light beams emitted from the optical gain media is incident on the dispersing element. The dispersing element disperses the light beams emitted from the optical gain media into light beams of different wavelengths. The wavelength selecting element selects a light beam of a predetermined wavelength from the light beams of different wavelengths into which the light beams emitted from the optical gain media are dispersed by the dispersing element. The light source device emits the light beam of the predetermined wavelength selected by the wavelength selecting element.

Since the optical gain media have gain wavelength bands that partially overlap and different maximum gain wavelengths, light oscillation can be achieved over a continuous wavelength range obtained by combining the gain wavelength bands of the individual optical gain media. As a result, stable wavelength sweeping can be performed over a wide wavelength band.

Further features of the present invention will become apparent from the following description of exemplary embodiments with reference to the attached drawings.

### BRIEF DESCRIPTION OF THE DRAWINGS

FIGS. 1A and 1B illustrate a light source device according to a first embodiment of the present invention.

FIGS. 2A to 2C are diagrams used to describe the light source device according to the first embodiment of the present invention.

FIG. 3 illustrates a measurement device including the light source device according to the first embodiment of the present invention.

FIG. 4 illustrates a measurement device including a light source device according to a fourth embodiment of the present invention.

FIG. 5 is a graph of the gain-wavelength characteristics of optical gain media included in the light source device according to the first embodiment of the present invention.

FIG. 6 illustrates an example of timing at which switching between the optical gain media is performed in the light source device according to the first embodiment of the present invention.

FIG. 7 illustrates a K clock counter.

FIGS. 8A and 8B illustrate a light source device according to a second embodiment of the present invention.

FIGS. 9A and 9B illustrate examples of timing at which switching between the optical gain media is performed.

FIGS. 10A and 10B also illustrate examples of timing at which switching between the optical gain media is performed.

FIG. 11 illustrates a measurement device including a light source device according to a third embodiment of the present invention.

FIGS. 12A and 12B illustrate a light source device according to a fifth embodiment of the present invention.

FIG. 13 illustrates a measurement device including a light source device according to a sixth embodiment of the present invention.

FIG. 14 is a graph showing the wavelength variation in the light source device according to the sixth embodiment of the present invention.

FIG. 15 illustrates a measurement device including a light source device according to a seventh embodiment of the present invention.

FIG. 16 is a graph showing the wavelength variation in the light source device according to the seventh embodiment of the present invention.

FIG. 17 illustrates an example of a measurement device including a light source device according to an eight embodiment of the present invention.

FIG. 18 illustrates another example of a measurement device including a light source device according to the eight embodiment of the present invention.

FIGS. 19A to 19C illustrate a light source device according to a ninth embodiment of the present invention.

FIG. 20 illustrates a light source device according to a tenth embodiment of the present invention.

FIG. 21 illustrates an imaging apparatus including a light source device according to an eleventh embodiment of the present invention.

FIG. 22 illustrates a light source device of the related art.

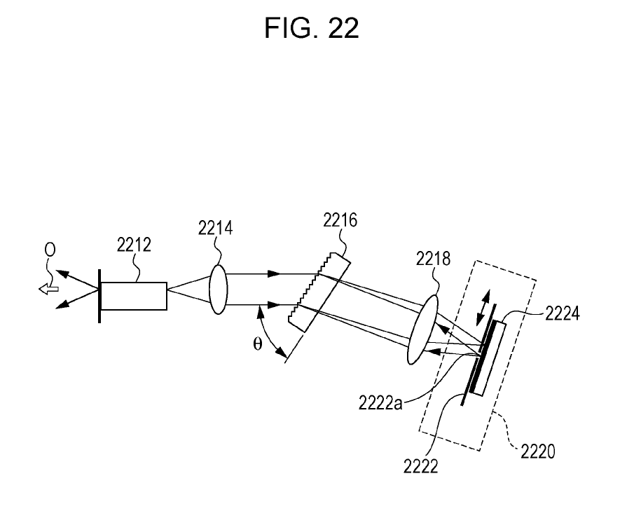

FIG. 23 illustrates a light source device of the related art.

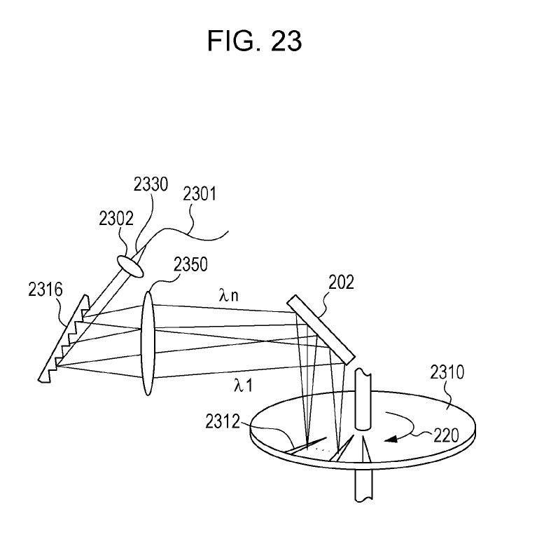

### DESCRIPTION OF THE EMBODIMENTS

A light source device according to an embodiment of the present invention includes a plurality of optical gain media having gain wavelength bands that partially overlap and different maximum gain wavelengths. The optical gain media are arranged next to each other and light beams in the respective gain wavelength bands are successively oscillated, so that wavelength sweeping over a wide wavelength band can be achieved.

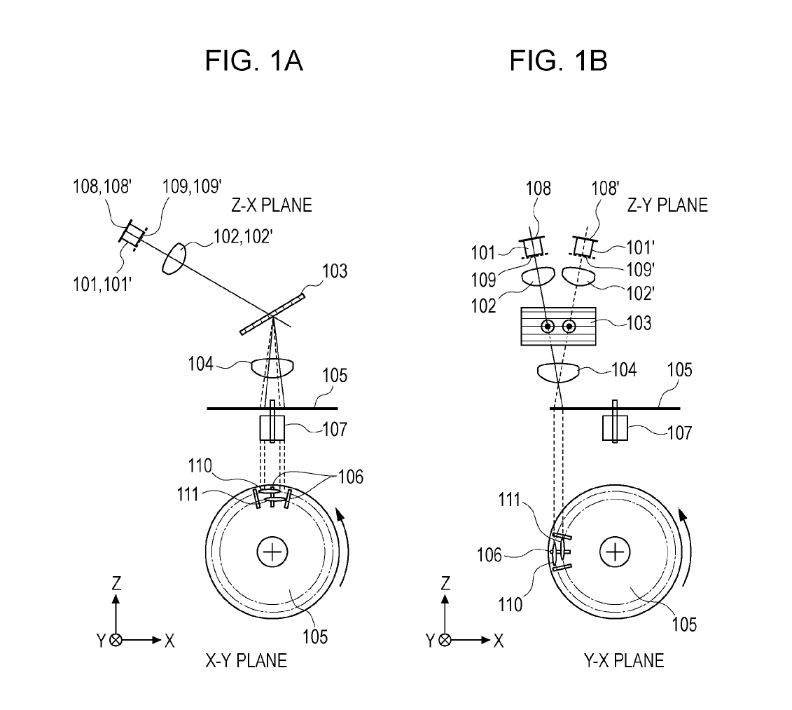

A light source device according to an embodiment of the present invention will be described with reference to FIG. 1.

The light source device illustrated in FIG. 1 includes semiconductor optical amplifiers as the optical gain media; a diffraction grating as a dispersing element that disperses light emitted from each optical gain medium into light beams of different wavelengths; and a rotating disc having strip-shaped mirrors as a selecting element that selects a light beam of a predetermined wavelength from the light beams of different wavelengths emitted from the dispersing element.

FIG. 1A illustrates a Z-X plane and an X-Y plane in an X-Y-Z coordinate system. FIG. 1B illustrates a Z-Y plane and a Y-X plane in the X-Y-Z coordinate system.

Referring to FIGS. 1A and 1B, semiconductor optical amplifiers 101 and 101′ have a function of generating spontaneous emission light in a semiconductor layer and emitting the generated light after amplification thereof. The device illustrated in FIG. 1 includes a plurality of optical gain media.

The semiconductor optical amplifiers 101 and 101′ have end surfaces that are coated with antireflection films 109 and 109′, respectively, and are arranged such that the end surfaces face a diffraction grating 103 with respective collimator lenses 102 and 102′ located therebetween.

A rotating disc 105 has a surface that has been subjected to an antireflection process and on which a plurality of strip-shaped reflective members (mirrors) 106 are arranged so as to extend radially around the center of the rotating disc 105. The rotating disc 105 is rotated by a motor 107.

The semiconductor optical amplifier 101 has a gain wavelength band of, for example, 780 to 850 nm, and the semiconductor optical amplifier 101′ has a gain wavelength band of, for example, 810 to 880 nm. Thus, the gain wavelength bands partially overlap.

Accordingly, stable wavelength sweeping can be achieved over a continuous wavelength band including the gain wavelength bands of the respective optical gain media.

Light beams emitted from the semiconductor optical amplifiers 101 and 101′ are caused to pass through the collimator lenses 102 and 102′, respectively, and are incident on the diffraction grating 103 such that optical axes thereof are on a plane including one of the grooves in the diffraction grating 103.

The light beam emitted from the semiconductor optical amplifier 101, which has a gain wavelength band at the short-wavelength side, is angularly dispersed into light beams of different wavelengths by the diffraction grating 103. The light beams pass through a condensing lens 104 and converge on the rotating disc 105 so as to form an elliptical pattern 111 thereon.

The light beam emitted from the semiconductor optical amplifier 101′, which has a gain wavelength band at the long-wavelength side, converge on the rotating disc 105 so as to form an elliptical pattern 110 thereon.

The elliptical patterns 111 and 110 correspond to the light beams of different wavelength bands emitted from the respective optical gain media. The light beams of different wavelength bands are arranged in the radial direction of the rotating disc 105.

For example, the elliptical pattern 111 is formed by light beams within a wavelength band of λ1 to λ11, and the elliptical pattern 110 is formed by light beams within a wavelength band of λ9 to λ20.

The light beams having the wavelengths λ1 to λ20 are successively selected from the light beams within the two wavelength bands and emitted. In other words, the oscillation wavelength can be varied continuously.

More specifically, the light beam having a desired wavelength is selected from the light beams within the two wavelength bands by the reflective members 106, and the selected light beam is returned to the semiconductor optical amplifiers 101 and 101′.

The semiconductor optical amplifiers 101 and 101′ also have end surfaces that are coated with reflective films 108 and 108′, respectively. These end surfaces and the reflective members 106 form an optical resonator in which the selected light beam is amplified. Then, emission light is extracted by guiding light that passes through the diffraction grating 103 into an optical input coupler (not shown) disposed near the diffraction grating 103.

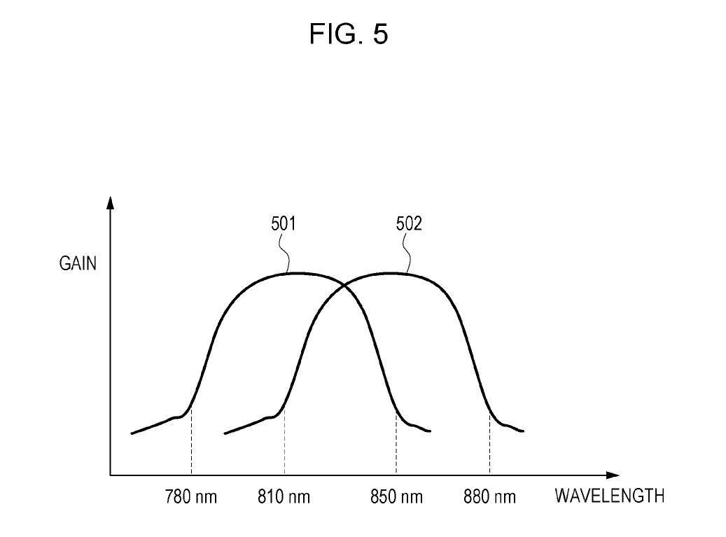

FIG. 5 shows the gain-wavelength characteristics of the optical gain media in the gain wavelength bands thereof in the case where the two semiconductor optical amplifiers 101 and 101′ are used as the optical gain media.

The semiconductor optical amplifier 101 has a gain-wavelength characteristic 501 in which the gain wavelength band is 780 to 850 nm and the maximum gain wavelength is 815 nm.

The semiconductor optical amplifier 101′ has a gain-wavelength characteristic 502 in which the gain wavelength band is 810 to 880 nm and the maximum gain wavelength is 845 nm. In this example, the gain wavelength bands overlap in the range of 810 to 850 nm.

As is clear from FIG. 5, a certain continuous gain wavelength band (780 to 880 nm in the example of FIG. 5) can be obtained by selectively using a plurality of optical gain media.

In the light source device according to the embodiment of the present invention, each of the light beams generated by the optical gain media is incident on a dispersing element, such as a diffraction grating, and is dispersed into light beams of different wavelengths by the dispersing element.

Components of the light source device are spatially arranged so that end surfaces of the first and second optical gain media and a wavelength selecting element form an optical resonator and the light beams of different wavelengths emitted from the dispersing element are successively selected and emitted from the optical resonator when the wavelength selecting element is driven in a certain direction. Emission of a light beam of a certain wavelength band from one of a plurality of optical gain media and emission of a light beam of another wavelength band from another one of the optical gain media can be performed successively.

A case in which a diffraction grating is used as the dispersing element will now be described.

A transmission diffraction grating satisfies the following Equation (1).

sin α−sin β=Nmλ (1)

In Equation (1), α is an incident angle of light on the diffraction grating and β is an exit angle of light from the diffraction grating. Both the incident angle and the exit angle are angles from the normal line of the diffraction grating, and angles in the counterclockwise direction are defined as positive.

In addition, N is the number of lines per unit length in the diffraction grating, and m is the order of diffraction. Here, it is assumed that N=1.2 lines/μm, m=+1, and λ=λo±Δλ, where λo=0.84 μm and Δλ=0.04 μm. Since ±Δλ=0.04 μm, the wavelength variable range is 80 nm.

A volume hologram diffraction grating generally has a high diffraction efficiency η, and η is 0.9 (90%) or more when α=β.

When λ=λo, α and β are determined from Equation (1) as follows:

α=−β=30.265° (2)

When the incident angle α is fixed to α=30.265°, exit angles βs and βe obtained when the wavelengths are λs=λo−Δλ=0.80 μm and λe=λo+Δλ=0.88 μm are calculated from Equation (1) as follows:

−βs=27.129° (3)

−βe=33.504° (4)

For the convenience of explanation, two optical gain media L1 and L2, each of which has a gain wavelength bandwidth (band) of 50 nm, are considered. It is assumed that the gain wavelength of the optical gain medium L1 is 0.8 to 0.85 μm, and that of the optical gain medium L2 is 0.83 to 0.88 μm.

When the gain wavelength bands of the optical gain media L1 and L2 are combined, the combined range is 0.80 to 0.88 μm. Thus, the gain wavelength bandwidth is 80 nm. The gain wavelength bands overlap in the range of 0.83 to 0.85 μm.

Light beams from the optical gain media L1 and L2 are incident on the above-described diffraction grating. The light beams may be incident on the diffraction grating at the same angle. In this case, as is clear from Equation (1), the exit angle (diffraction angle) is determined only by λ.

With the above-described arrangement, the light beams from the optical gain media L1 and L2 are emitted from the diffraction grating at the same exit angle (diffraction angle) in the overlapping wavelength range. The wavelengths and exit angles of the light beams are determined from Equations (2), (3), and (4) as follows:
L1 Wavelength 0.8 μm Exit Angle 27.129°
   Wavelength 0.84 μm Exit Angle 30.265°
L2 Wavelength 0.84 μm Exit Angle 30.265°
   Wavelength 0.88 μm Exit Angle 33.504°

In the overlapping wavelength range of 0.83 to 0.85 μm, the optical gain media L1 and L2 may emit the light beams simultaneously. Alternatively, the optical gain medium that emits light may be switched from the optical gain medium L1 to the optical gain medium L2 in the overlapping wavelength range.

A switching time for switching the optical gain medium that emits light may be necessary in practice. In such a case, to provide a light-emission rising time, an incident angle α1 of the light beam from the optical amplifying medium having the gain wavelength band at the short-wavelength side on the diffraction grating and an incident angle α2 of the light beam from the optical amplifying medium having the gain wavelength band at the long-wavelength side on the diffraction grating are set so as to satisfy α1>α2.

In this case, when wavelength sweeping is performed from the short wavelength side, the oscillation wavelength from the optical amplifying medium having the gain wavelength band at the long wavelength side is generated with a time delay. Thus, a light-emission rising time can be provided.

When α1>α2 is satisfied, also in the case where wavelength sweeping is performed from the long wavelength side to the short wavelength side, the wavelength is generated with a time delay upon switching between the optical amplifying media. Therefore, also in this case, a light-emission rising time can be provided.

Although the case in which two optical amplifying media are provided is described above, the number of optical amplifying media may instead be three or more.

In the light source device according to the present embodiment, the light beams may be incident on the diffraction grating by the following two methods.

According to a first method, the light beams are incident on the diffraction grating such that optical axes thereof are on a plane including one of the grooves so that the sweeping mechanism simply continuously sweeps the oscillation wavelength by using the wavelength selecting element.

According to a second method, the light beams are incident on the diffraction grating at different incident angles so that the oscillation wavelengths overlap and the oscillation is performed after a time delay that corresponds to the light-emission rising time. As a result, the wavelength is swept continuously.

The function of the condensing lens that causes the diffracted light beams emitted from the diffraction grating to converge on the wavelength selecting element will now be described. The diffracted light beams of different wavelengths emitted from the diffraction grating are collimated light beams, and are incident on the condensing lens at different incident angles.

When Δθg is a dispersion angle of the diffraction grating and f_{fo} is a focal distance of the condensing lens, the dispersion width d on the wavelength selecting element can be calculated as follows:

d=f_{fo}×Δθg (5)

Specific values will be shown below.

The wavelengths and exit angles are determined from Equations (3), and (4) as follows:
Wavelength 0.8 μm Exit Angle 27.129°
Wavelength 0.88 μm Exit Angle 33.504°

The dispersion angle Δθg corresponding to the wavelength range of 0.8 to 0.88 μm is Δθg=6.375°.

When the focal distance f_{fo} of the condensing lens is f_{fo}=7.5 mm, the dispersion width d corresponding to the wavelength range of 0.8 to 0.88 μm is calculated from Equation (5) as d=834 μm.

The wavelength selecting unit includes, for example, a rotating disc having a line of strip-shaped portions formed thereon, the strip-shaped portions serving as reflective mirrors.

The width of the strip-shaped portions is set to, for example, 10 μm, and the opening slits are arranged along the circumference of the rotating disc. Thus, a light source capable of sweeping the wavelength from 0.8 to 0.88 μm by rotating the rotating disc is provided.

An optical coherence tomography (OCT) apparatus in which the light source device according to the embodiment of the present invention can be suitably used will now be described.

In the OCT apparatus, the depth resolution δL and the wavelength sweeping range Δλ satisfy the relationship of Equation (6).

$$Δλ = \frac{2 \cdot ln 2 \cdot {λ}_{0}^{2}}{π \cdot n \cdot δ L} \qquad ( 6 )$$

In Equation (6), λ₀ is the center wavelength of the sweeping wavelength range and n is the refractive index of the inspection object. When the inspection object is a tissue in a human eye, n is about 1.38.

Here, an OCT apparatus is considered which uses light in the 800-nm wavelength band with the sweeping center wavelength λ₀ of 840 nm. When the depth resolution δL for the inspection object to be observed is expected to be 3 μm or higher, the required wavelength sweeping range Δλ is calculated from Equation (6) as 80 nm or more.

As described above with reference to FIG. 5, the wavelength sweeping range Δλ of 80 nm or more can be achieved by using a plurality of optical gain media.

Embodiments of the present invention will now be described with reference to the drawings.

### First Embodiment

A light source device according to a first embodiment of the present invention will be described with reference to FIG. 1.

The light source device illustrated in FIG. 1 includes semiconductor optical amplifiers as optical gain media; a diffraction grating as a dispersing element that disperses light emitted from each optical gain medium into light beams of different wavelengths; and a rotating disc having strip-shaped mirrors as a selecting element that selects a light beam of a predetermined wavelength from the light beams of different wavelengths emitted from by the dispersing element.

FIG. 1A illustrates a Z-X plane in a three-dimensional X-Y-Z coordinate system viewed in the direction from the negative side to the positive side of the Y axis.

Semiconductor optical amplifiers 101 and 101′ generate or amplify spontaneous emission light. The semiconductor optical amplifiers 101 and 101′ include active layers.

The semiconductor optical amplifiers 101 and 101′ are coated with highly reflective films 108 and 108′, which serve as resonator mirrors for generating laser oscillation, at one end thereof, and with antireflection films 109 and 109′ at the other end thereof. Collimator lenses 102 and 102′ collimate divergent light beams emitted from the active layers at the side at which the antireflection films 109 and 109′ are provided.

A transmission diffraction grating 103 disperses the collimated light beams into light beams of different wavelengths. The diffraction grating 103 is a volume hologram diffraction grating having 1,200 grooves per millimeter.

A condensing lens 104 causes the light beams of different wavelengths to converge on a rotating disc 105. In this example, the focal distance of the condensing lens 104 is f_{fo}.

The rotating disc 105 has a surface that has been subjected to an antireflection process and on which strip-shaped members 106 are arranged. The strip-shaped members 106 are arranged with constant intervals therebetween so as to extend radially around the center of the rotating disc 105, as illustrated in FIGS. 1A and 1B. Each of the strip-shaped members 106 is reflective.

The rotating disc 105 is fixed to a rotating shaft of a motor 107 such that rotation centers thereof coincides with each other.

FIG. 1B illustrates a Z-Y plane in the three-dimensional X-Y-Z coordinate system viewed in the direction from the negative side to the positive side of the X axis.

The optical gain media 101 and 101′ have gain wavelength bands of, for example, 800 to 850 nm and 830 to 880 nm, respectively.

The two optical gain media 101 and 101′ have an overlapping gain wavelength band (830 to 850 nm in this example). The optical gain medium 101 has a gain wavelength band at a short-wavelength side, and the optical gain medium 101′ has a gain wavelength band at a long-wavelength side.

The positional relationship between the optical gain media 101 and 101′ and light beams 111 and 110 on the rotating disc 105 will now be described.

First, the distances from the rotation center of the rotating disc 105 to the light beams 111 and 110 will be explained. The light beams that pass through the collimator lenses 102 and 102′ are at an angle of ΔΦ in a plane including one of the grooves of the diffraction grating 103.

Therefore, no diffraction is caused by the diffraction grating 103. Accordingly, the light beams 111 and 110 are projected onto the rotating disc 105 through the condensing lens 104 at positions spaced from the rotation center of the rotating disc 105 in the radial direction by a distance dΦ determined by the following Equation (7).

dΦ=ΔΦ×f_{fo} (7)

When, for example, f_{fo}=7.5 mm and ΔΦ=10°, dΦ is calculated as dΦ=1.3 mm.

Next, the positional relationship between the light beams 111 and 110 in the tangential direction of the rotating disc 105 will be explained.

Referring to FIG. 1A, the light beams emitted from the optical gain media 101 and 101′ and diffracted by the diffraction grating 103 are shown by the solid line and the dotted line, respectively.

In the case where the incident angle a is set to 30.265°, at which the diffraction efficiency is at a maximum, the wavelength dependency of the exit angles of the light beams emitted from the diffraction grating 103 can be determined from Equations (1) and (2) as follows:

| | |
|---|---|
| Wavelength 0.80 μm | Exit Angle 27.129° |
| Wavelength 0.83 μm | Exit Angle 29.472° |
| Wavelength 0.84 μm | Exit Angle 30.265° |
| Wavelength 0.85 μm | Exit Angle 31.064° |
| Wavelength 0.88 μm | Exit Angle 33.504° |

The wavelength of 0.84 μm is in the overlapping range in which the gain wavelength bands of the optical gain media 101 and 101′ overlap. Therefore, the position corresponding to this wavelength is defined as the origin. When the focal distance f_{fo} of the condensing lens 104 is 7.5 mm, positions of the light beams from the optical gain media 101 and 101′ can be determined from Equation (5) as follows:

| | |
|---|---|
| Wavelength 0.80 μm | Position for this Wavelength −410 μm |
| Wavelength 0.83 μm | Position for this Wavelength −103 μm |
| Wavelength 0.84 μm | Position for this Wavelength 0 μm |
| Wavelength 0.85 μm | Position for this Wavelength +105 μm |
| Wavelength 0.88 μm | Position for this Wavelength +423 μm |

When the gain wavelength bands of the optical gain media 101 and 101′ are 800 to 850 nm and 830 to 880 nm, respectively, as described above, the light beams from the optical gain medium 101 are dispersed in the range of −410 μm to +105 μm and the light beams from the optical gain medium 101′ are dispersed in the range of −103 μm to +423 μm in the tangential direction of the rotating disc 105.

The two optical gain media have a common gain wavelength range that corresponds to the region of −103 μm to +105 μm with the position corresponding to the wavelength of 0.84 μm at the origin.

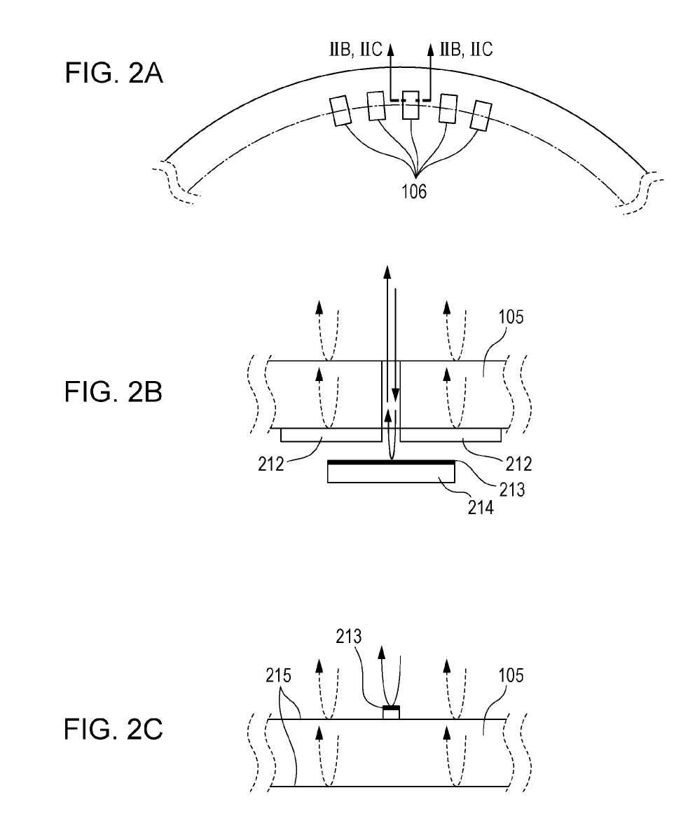

Further explanation will be given with reference to FIGS. 2A to 2C.

FIGS. 2A to 2C illustrate enlarged views of the rotating disc 105. FIG. 2A is an enlarged view of the strip-shaped members 106. As described above, the intervals between the strip-shaped members 106 are set to be larger than or equal to the dispersion width d (=834 μm) corresponding to the wavelength range of 800 to 880 nm.

The strip-shaped members 106 are arranged with the above-described intervals therebetween along the circumference centered on the rotation center of the rotating disc 105. The width of the strip-shaped members 106 is determined by, for example, aberrations of the condensing lens 104 and the diffraction limit, and may be several micrometers to several tens of micrometers. The length of the strip-shaped members 106 in the longitudinal direction may be several millimeters.

FIGS. 2B and 2C are sectional views illustrating two types of strip-shaped members 106. The structure of FIG. 2B is called a space pattern, and a transmissive slit opening used to select a wavelength is formed in the rotating disc 105 through a light blocking member 212. In FIG. 2B, reference numeral 214 denotes a reflective member and 213 denotes a reflective surface.

The structure of FIG. 2C is called a line pattern. In this structure, the rotating disc 105 is coated with an antireflection film 215, and a reflective strip-shaped pattern 213 having a wavelength selecting function is formed on the rotating disc 105.

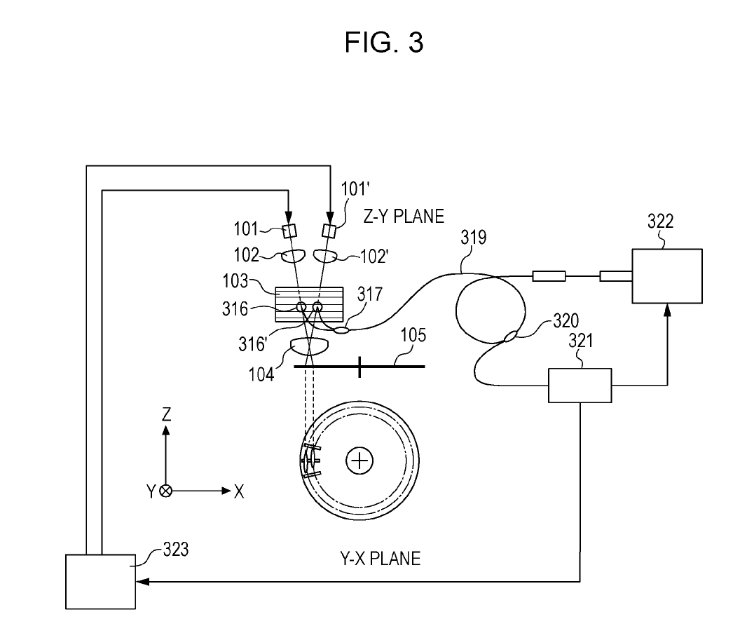

A measurement apparatus including the light source device according to the first embodiment of the present invention will now be described with reference to FIG. 3.

In FIG. 3, components explained above with reference to FIGS. 1A and 1B are denoted by the same reference numerals, and explanations thereof are thus omitted.

Optical input couplers 316 and 316′ are used to extract the light beams generated by the optical gain media 101 and 101′. An optical multiplexer 317 multiplexes the light beams input thereto through the optical input couplers 316 and 316′.

The light output from the optical multiplexer 317 is guided to an optical branching coupler 320 through a waveguide 319.

The optical branching coupler 320 branches the light guided thereto into light that is input to an OCT apparatus 322, which is a measurement apparatus, and light that is input to a wavelength detection unit 321, which detects a wavelength. The wavelength detection unit 321 counts, for example, the number of waves that corresponds to the wavelength change.

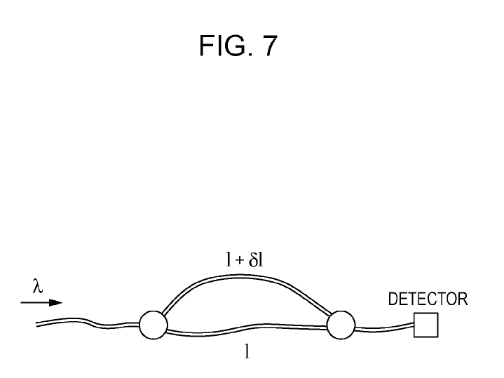

The wavelength detection unit 321 is called a K-clock counter, the principle of which is similar to that of a Mach-Zehnder interferometer illustrated in FIG. 7.

An output from the wavelength detection unit 321 is input to an optical-gain-medium driver 323 that controls driving power supplies of the optical gain media 101 and 101′ and switches thereof. The optical-gain-medium driver 323 controls the operation of the optical gain media 101 and 101′ on the basis of the information obtained by the wavelength detection unit 321.

The positional relationship between the rotation center of the rotating disc 105 and the projected light beams will now be described. As described above, the rotation center of the rotating disc 105 is on the extension lines of the strip-shaped members 106 in the longitudinal direction thereof.

The rotation center of the rotating disc 105 is arranged so that the longitudinal direction of the strip-shaped member 106 at the position corresponding to the switching wavelength 840 nm of the optical gain media 101 and 101′ is perpendicular to the major axes of the elliptical patterns formed on the rotating disc 105 by the light beams from the optical gain media 101 and 101′.

The driving operation will now be described with reference to FIGS. 1A, 1B, and 3. First, the optical-gain-medium driver 323 sets the power supply for the optical gain medium 101 to HIGH and the power supply for the optical gain medium 101′ to LOW.

Accordingly, the active layer in the optical gain medium 101 radiates light. A part of the radiated light is emitted through the antireflection film 109, is collimated by the collimator lens 102, and is incident on the diffraction grating 103.

The light incident on the diffraction grating 103 is diffracted into light beams of different wavelengths. The condensing lens 104 causes the light beams to converge on one of the strip-shaped members 106 of the rotating disc 105 so as to form an elliptical pattern 111 having a length of about 500 μm along the long axis thereof.

The rotating disc 105 rotates in the direction shown by the arrow in FIGS. 1A and 1B. Assuming that the position corresponding to the wavelength of 840 nm is the origin, when one of the strip-shaped members 106 on the rotating disc 105 reaches the position of −410 μm, the reflective surface of the strip-shaped member 106, which has the wave selecting function, starts to reflect the light beam with the wavelength of 800 nm.

The reflected divergent light beam with the wavelength of 800 nm passes through the condensing lens 104 and is incident on the diffraction grating 103.

Then, the light beam is emitted from the diffraction grating 103 toward the collimator lens 102, passes through the collimator lens 102, and returns to the optical gain medium 101. Since an end surface of the optical gain medium 101 is coated with the highly reflective film 108, an optical resonator is formed by the end surface and the reflective mirror in the wavelength selecting unit. As a result, laser oscillation occurs at the wavelength of 800 nm.

The oscillated light beam is collimated by the collimator lens 102 and is incident on the diffraction grating 103 again. Although the diffraction grating 103 diffracts 90% or more of the light incident thereon, several percent of the incident light is simply transmitted through the diffraction grating 103.

The thus-transmitted light is guided to the waveguide 319 by the optical input coupler 316, and is input to the OCT apparatus 322 and the wavelength detection unit 321.

The OCT apparatus 322 uses the light input thereto to obtain a tomographic image of an inspection object. The wavelength detection unit 321 uses the light input thereto to count and monitor the number of waves.

The initial value of the number of waves to be converted into the wavelength is determined in advance by, for example, measurement, calculation, or monitoring.

After the oscillation at the wavelength of 800 nm, the wavelength gradually changes to 830 nm while the position of the strip-shaped member 106 gradually changes from −410 μm to −103 μm. Then, when the position of the strip-shaped member 106 reaches 0 μm, the oscillation wavelength reaches 840 nm.

The wavelength is detected by the wavelength detection unit 321. When the detected wavelength reaches a wavelength in the overlapping range of the gain wavelength bands, the optical-gain-medium driver 323 switches the power supply of the optical gain medium 101 to LOW and the power supply of the optical gain medium 101′ to HIGH.

After the power supply of the optical gain medium 101′ is switched to HIGH, the oscillation wavelength changes to 850 nm while the position of the strip-shaped member 106 in the wavelength selecting unit changes to +105 μm. Then, when the position of the strip-shaped member 106 reaches +423 μm, the oscillation wavelength reaches 880 nm.

When the position of the strip-shaped member 106 is changed from −410 μm to +423 μm, the driving states of the optical gain media are switched within the period in which the position of the strip-shaped member 106 is changed from −103 μm to +105 μm. As a result, a light source device capable of performing continuous wavelength sweeping over a wavelength sweeping range of 800 to 880 nm is provided.

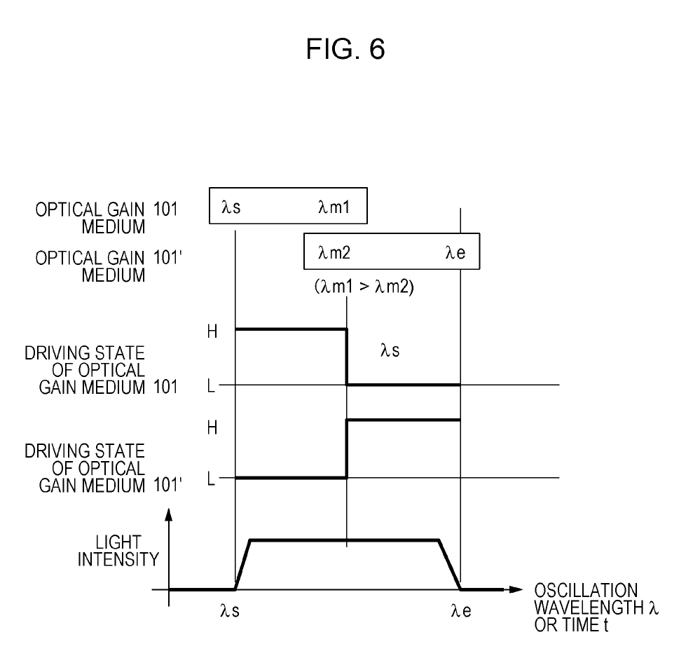

FIG. 6 illustrates the timing at which the switching is performed.

In FIG. 6, switching from the optical gain medium 101 to the optical gain medium 101′ is performed while the wavelength is between λm1=830 nm and λm2=850 nm. Accordingly, continuous wavelength sweeping can be performed in the wavelength range of λs=800 nm to λe=880 nm.

As described above, when one of the strip-shaped members 106 is moved from −410 μm to +423 μm, a single sweeping operation is performed over a certain sweeping range.

Since the strip-shaped members 106 are arranged with intervals that are larger than or equal to the dispersion width d (=834 μm), the sweeping operation can be repeatedly performed by the following strip-shaped members 106.

In embodiments of the present invention, the optical gain media used to amplify light may be, for example, active layers included in semiconductor lasers, active layers included in semiconductor optical amplifiers (SOAs), rare-earth-doped (ion-doped) optical fibers containing erbium, neodymium, etc., or dye-doped optical fibers in which dye is doped to amplify light.

Semiconductor lasers or SOAs may be used since they are small and allow high-speed control. In such a case, a small light source device that allows high-speed control can be provided.

The active layers included in the semiconductor lasers or SOAs may be formed of, for example, compound semiconductors used in common semiconductor lasers. Examples of such a compound semiconductor include InGaAs-based, InAsP-based, GaAlSb-based, GaAsP-based, AlGaAs-based, and GaN-based compound semiconductors.

These active layers have a gain center wavelength of, for example, 840 nm, 1060 nm, 1150 nm, 1300 nm, or 1550 nm, and may be selected in accordance with the use of the light source device.

Rare-earth-doped optical fibers are suitable for achieving a high gain and high noise performance. Dye-doped optical fibers are advantageous in that they provide the added versatility of selectable wavelengths when a fluorescent dye material and a host material therefor are appropriately selected.

In embodiments of the present invention, the dispersing element that disperses light into light beams of different wavelengths may be a static element such as a diffraction grating (transmissive or reflective), a prism, or a combination of a diffraction grating and a prism.

The dispersing element may be formed of a single element so that the size of the light source device can be reduced.

The wavelength selecting element may be, for example, a light blocking member having openings that allow light to pass therethrough. Alternatively, various spatial modulation elements may be used. Examples of spatial modulation elements include an element (light valve) that has one or more small openings and that reflects or transmits light beams that reach the openings, an acousto-optic (AO) device, which is a progressive diffraction grating, or an electro-optical (EO) device.

### Second Embodiment

Also in the following description, components having similar structures are denoted by the same reference numerals even when the components are shown in different figures, and explanations thereof are thus omitted.

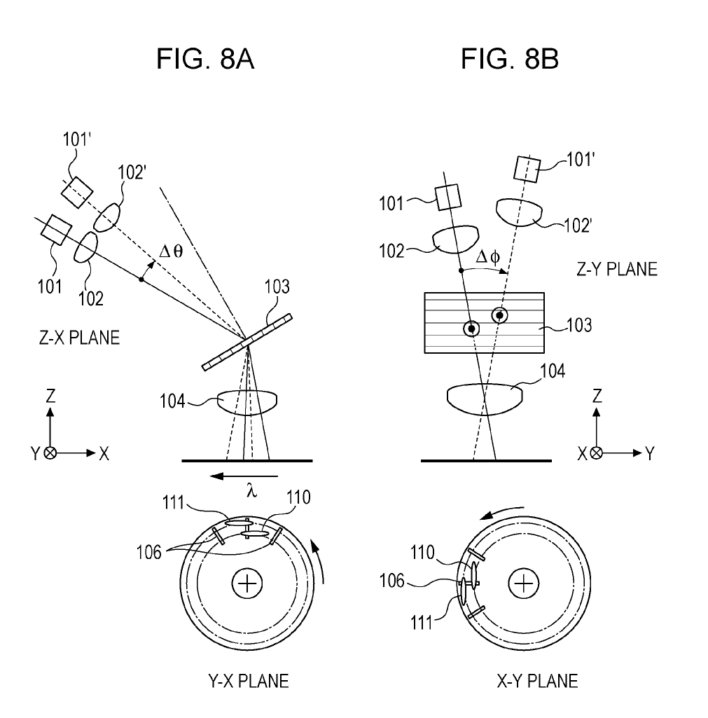

A second embodiment will be described with reference to FIGS. 8A to 10B. In the first embodiment, the light beams generated by the two optical gain media are incident on the diffraction grating at the same incident angle.

Accordingly, when the wavelength-dispersed light beams are projected onto the rotating disc so as to form the elliptical patterns, the wavelength overlapping areas of the light beams are at the same position on the rotating disc.

In the second embodiment, the wavelength overlapping areas on the rotating disc are purposely shifted from each other.

The first embodiment can be applied when the wavelength switching time is negligibly small compared to the wavelength sweeping time. However, in the case where the wavelength switching time is several to several tens of nanoseconds, oscillation at the predetermined wavelength is desirably started with a time delay that corresponds to the wavelength switching time when the switching between the optical gain medium is performed.

This can be achieved by causing the light beams from the two optical gain media to be incident on the diffraction grating at different incident angles instead of the same incident angle as in the first embodiment.

Similar to FIG. 1A, FIG. 8A illustrates a Z-X plane viewed in the direction from the negative side to the positive side of the Y axis. Similar to the first embodiment, an optical gain medium 101′ emits a light beam having a gain wavelength band at a long-wavelength side. In FIG. 8A, the angle between the light beam from the optical gain medium 101′ and that from the optical gain medium 101 is Δθ.

Similar to FIG. 1B, FIG. 8B illustrates a Z-Y plane viewed in the direction from the negative side to the positive side of the X axis. In FIG. 8B, the angle between the light beam from the optical gain medium 101′ and that from the optical gain medium 101 is ΔΦ.

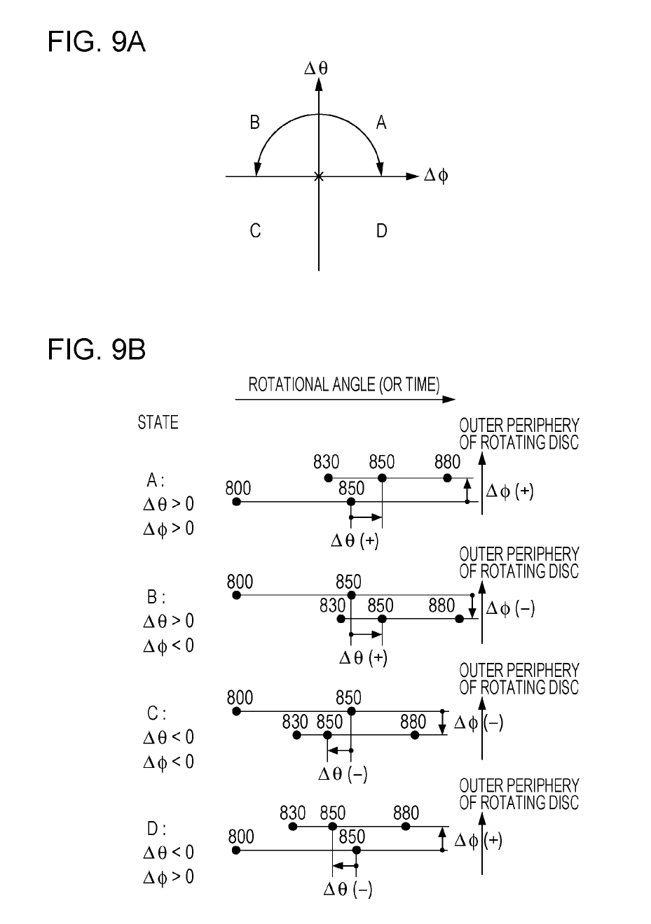

FIG. 9A is a graph for explaining the settings of the angles of chief rays of the light beams that are emitted from the two optical gain media 101 and 101′ and incident on the diffraction grating. In the graph, the vertical axis represents Δθ and the horizontal axis represents ΔΦ.

In the graph of FIG. 9A, the state in which Δθ and ΔΦ are both positive is defined as state A, the state in which Δθ is positive and ΔΦ is negative as state B, the state in which Δθ and ΔΦ are both negative as state C, and the state in which Δθ is negative and ΔΦ is positive as state D.

FIG. 9B illustrates the positional relationships between the wavelength-dispersed light beams on the rotating disc when the angles of chief rays of the light beams from the optical gain media 101 and 101′ are in states A, B, C, and D. The optical gain medium 101 has a gain wavelength band of 800 to 850 nm, and the optical gain medium 101′ has a gain wavelength band of 830 to 880 nm.

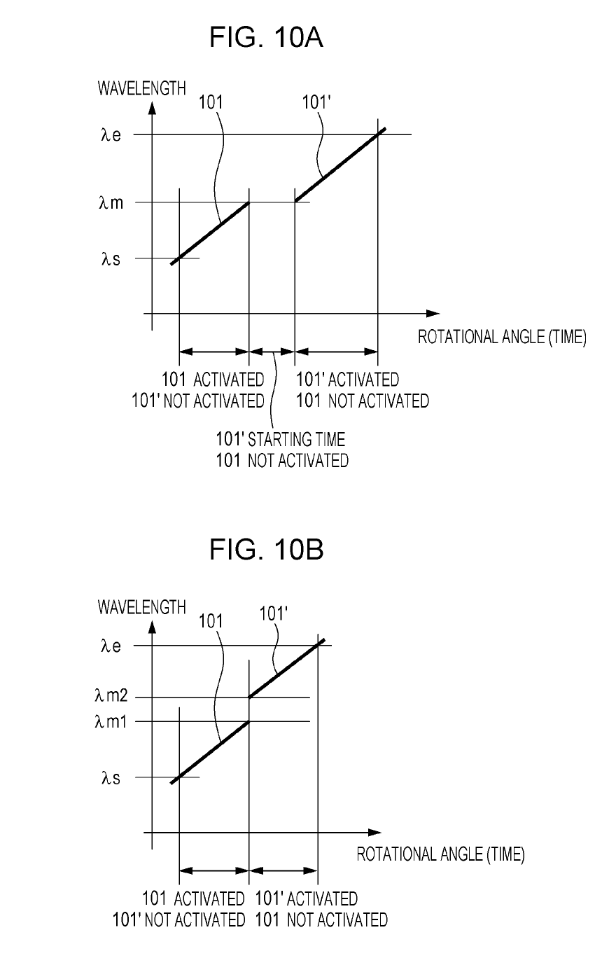

FIG. 10A is a graph showing the relationship between the rotational angle of the rotating disc and the oscillation wavelength λ in states A and B shown in FIG. 9B, and FIG. 10B is a graph showing the relationship between the rotational angle of the rotating disc and the oscillation wavelength λ in states C and D shown in FIG. 9B.

As illustrated in FIG. 9B, in states A and B, in which Δθ>0, when the wavelength of the light beam from the optical gain medium 101 at the short-wavelength side (800 to 850 nm) is 850 nm, the oscillation wavelength of the light beam from the optical gain medium 101′ (830 to 880 nm) is around 840 mm, which is smaller than 850 nm.

This means that, as illustrated in FIG. 10A, a switching time can be provided when the switching from the optical gain medium 101 to the optical gain medium 101′ is performed.

In states C and D, in which Δθ<0, when the wavelength of the light beam from the optical gain medium 101 at the short-wavelength side (800 to 850 nm) is 850 nm, the oscillation wavelength of the light beam from the optical gain medium 101′ (830 to 880 nm) is around 860 mm, which is greater than 850 nm.

This means that, as illustrated in FIG. 10B, no switching time can be provided when the switching from the optical gain medium 101 to the optical gain medium 101′ is performed, and a blank wavelength band is included in the sweeping wavelength range.

Therefore, in, for example, an OCT apparatus, a periodic structure of the inspection object at a depth that corresponds to the blank wavelength band cannot be included in an OCT image. Thus, there is a risk that states C and D, in which Δθ<0, will cause a problem when the light source device is used as an OCT light source.

It is clear from the above description that the first embodiment described with reference to FIG. 1 corresponds to the case in which Δθ=0 in the present embodiment.

Referring to FIG. 8B, when Δθ>0, the position at which the light beam from the optical gain medium 101′ at the long wavelength side is projected onto the rotating disc is outside the position at which the light beam from the optical gain medium 101 at the short wavelength side is projected onto the rotating disc in the radial direction around the rotation center.

Conversely, when Δθ<0, the position at which the light beam from the optical gain medium 101′ at the long wavelength side is projected onto the rotating disc is inside the position at which the light beam from the optical gain medium 101 at the short wavelength side is projected onto the rotating disc in the radial direction around the rotation center.

A device according to an embodiment of the present invention may have the following structure.

That is, when the optical gain media are denoted by M₁, M₂, . . . , Mₙ in order from the optical gain medium having the gain wavelength band at the short-wavelength side, and when angles of chief rays of the light beams emitted from the optical gain media M₁, M₂, . . . , Mₙ and incident on the diffraction grating with respect to a plane that includes a normal line of the diffraction grating and that is parallel to the direction of grooves in the diffraction grating are α₁, α₂, . . . , αₙ, respectively, where αₖ>αₖ₊₁ and k is a positive integer, the optical gain media M₁, M₂, . . . , Mₙ are arranged in an optical resonator including the wavelength selecting element so that angles between the chief rays Δθₙ (Δθ₁=α₁−α₂, Δθ₂=α₂−α₃, Δθₙ=αₙ−αₙ₊₁) satisfy Δθₙ (Δθ₁, Δθ₂, . . . , Δθₙ)≧0.

A device according to another embodiment of the present invention may have the following structure.

That is, when angles of chief rays of the light beams emitted from the optical gain media M₁, M₂, . . . , Mₙ and incident on the diffraction grating with respect to a plane that includes a normal line of the diffraction grating and that is perpendicular to the direction of grooves in the diffraction grating are β₁, β₂, . . . , βₙ, respectively, where βₖ>βₖ₊₁ and k is a positive integer, the optical gain media M₁, M₂, . . . , Mₙ are arranged so that angles between the chief rays ΔΦₙ (ΔΦ₁=β₁−β₂, ΔΦ₂=β₂−β₃, . . . , ΔΦₙ=βₙ−βₙ₊₁) satisfy ΔΦₙ (ΔΦ₁, ΔΦ₂, . . . , ΔΦₙ)≧0 or ΔΦₙ (ΔΦ₁, ΔΦ₂, . . . , ΔΦₙ)<0.

### Third Embodiment

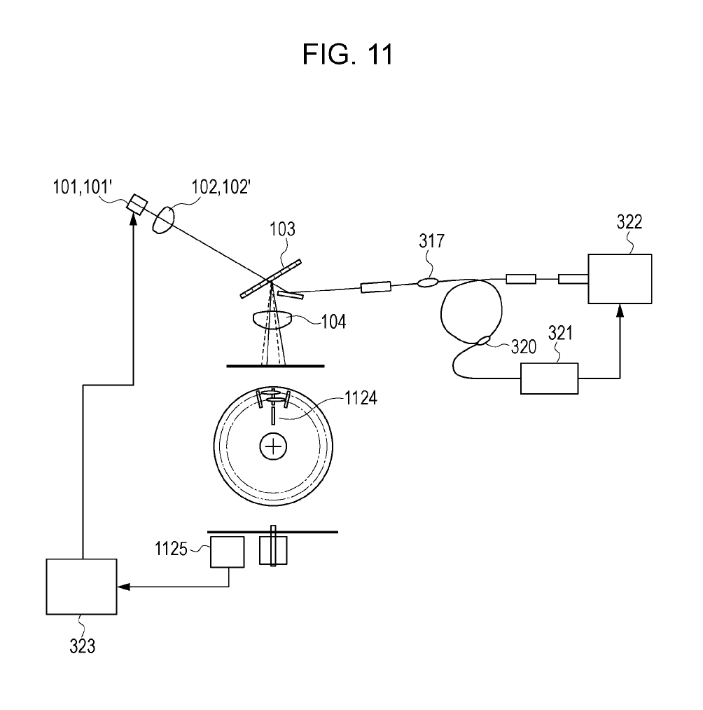

FIG. 11 illustrates an apparatus according to a third embodiment of the present invention. The apparatus illustrated in FIG. 11 mainly differs from the apparatus according to the first embodiment illustrated in FIG. 3 in that a wheel-origin detection mechanism 1125 and a wheel-origin detection slit 1124 are provided.

Other structures are similar to those in the apparatus illustrated in FIG. 3.

In the apparatus of the present embodiment, the wheel-origin detection mechanism 1125 detects the rotation origin of a wheel (rotating disc).

The wheel-origin detection slit 1124 is formed in the wheel (rotating disc). A switching timing signal based on which the switching between the optical gain media 101 and 101′ is performed is generated by using the rotation origin as a reference. The power supplies for the optical gain media 101 and 101′ are switched in response to the generated signal.

Since it is not necessary to use a signal from the wavelength detection unit 321, the switching operation can be stabilized and the wavelength sweeping can be simplified.

### Fourth Embodiment

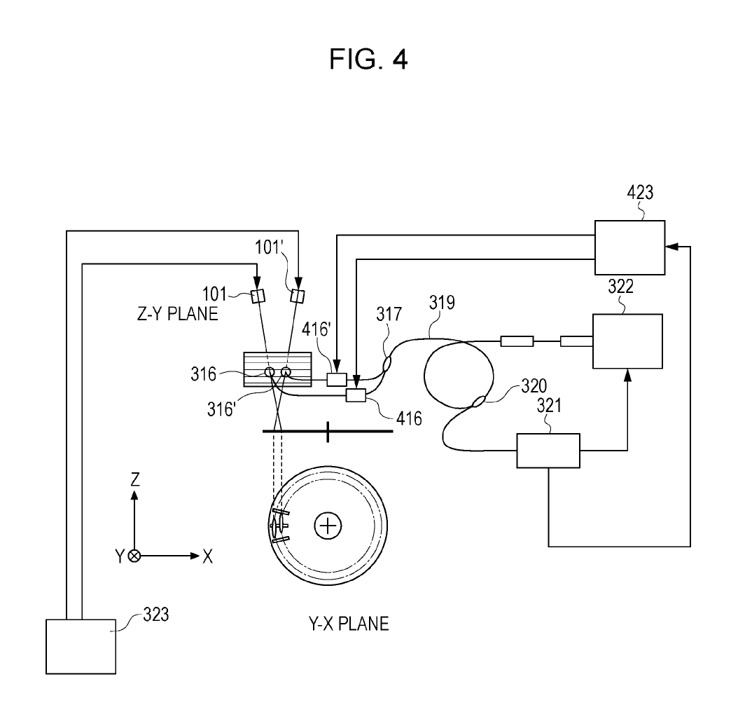

FIG. 4 is a schematic diagram illustrating an apparatus according to a fourth embodiment.

The apparatus according to the present embodiment mainly differs from the apparatus according to the first embodiment illustrated in FIG. 3 in that optical switches 416 and 416′ are provided in place of the switching mechanism for controlling (switching) the electrical ON-OFF states of the optical gain media 101 and 101′.

In the apparatus illustrated in FIG. 4, optical switches 416 and 416′ are disposed between the optical multiplexer 317 and the optical input couplers 316 and 316′. The optical switches 416 and 416′ are controlled by an optical switch drive 423 connected to the wavelength detection unit 321.

Thus, optical switches are disposed in optical paths used to couple the light beams of the respective wavelength bands with an optical coupler, and switching between the light beams of the respective wavelength bands is performed by using the optical switches.

In the apparatus of the present embodiment, the optical gain media 101 and 101′ are constantly set to the ON state without being switched, and the optical switch drive 423 receives an instruction regarding of the ON/OFF state based on the signal from the wavelength detection unit 321. The ON/OFF states of the optical switches 416 and 416′ are switched in accordance with the instruction.

The optical switches 416 and 416′ may be, for example, waveguide-type optical path switches using the electro-optical (EO) effect or the acousto-optic (AO) effect or bulk optical elements such as prisms, mirrors, or lenses.

### Fifth Embodiment

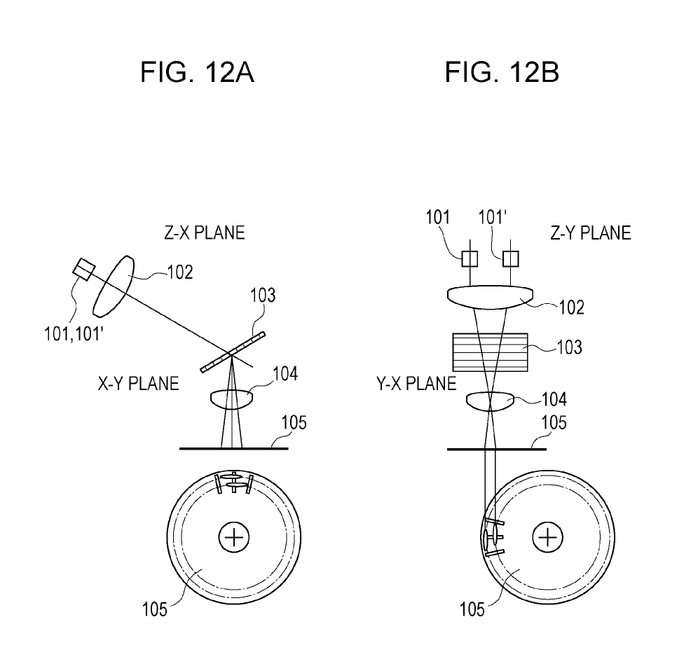

FIGS. 12A and 12B illustrate a light source device according to a fifth embodiment. The fifth embodiment corresponds to the case in which Δθ=0 and ΔΦ≠0 in the second embodiment described above with reference to FIGS. 8A and 8B.

Different from the above-described embodiments, a common collimator lens 102 is provided for the optical gain media 101 and 101′.

With this arrangement, the mounting process can be facilitated since the directions in which the light beams are emitted from the optical gain media 101 and 101′ are parallel to each other. In addition, since only one collimator 102 is provided, the optical system can be stabilized.

### Sixth Embodiment

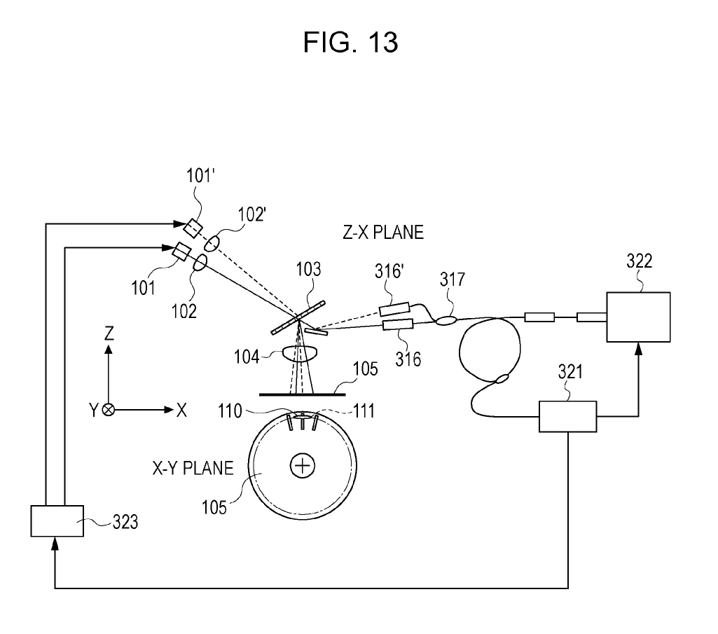

FIG. 13 illustrates an apparatus according to a sixth embodiment. The sixth embodiment corresponds to the case in which Δθ>0 and ΔΦ=0 in the second embodiment described above with reference to FIGS. 8A and 8B.

The structure of the apparatus illustrated in FIG. 13 is similar to that of the apparatus illustrated in FIG. 3 except that Δθ>0 and ΔΦ=0.

In the apparatus according to the present embodiment, the light beams from the optical gain media 101 and 101′ are projected onto the rotating disc 105 at the same distance from the rotation center.

As described above, in the apparatus according to the first embodiment, the rotation center of the rotating disc 105 is arranged so that the longitudinal direction of the strip-shaped member 106 at the position corresponding to the switching wavelength 840 nm is perpendicular to the major axes of the elliptical patterns formed on the rotating disc 105 by the light beams from the optical gain media 101 and 101′.

Since ΔΦ≠0 in the first embodiment, the above-mentioned arrangement is applied to ensure the continuity of wavelength sweeping upon wavelength switching between the optical gain media 101 and 101′.

However, there may be a case in which it is difficult to adjust the position of the rotation center. In the apparatus of the present embodiment, since ΔΦ=0, the light beams from the optical gain media 101 and 101′ are projected onto the rotating disc 105 at the same position from the rotation center.

Accordingly, it is not necessary that the longitudinal direction of the strip-shaped member 106 be perpendicular to the major axes of the elliptical patterns formed by the wavelength-dispersed light beams projected onto the rotating disc 105. Thus, the restriction on the position of the rotation center of the rotating disc 105 can be reduced.

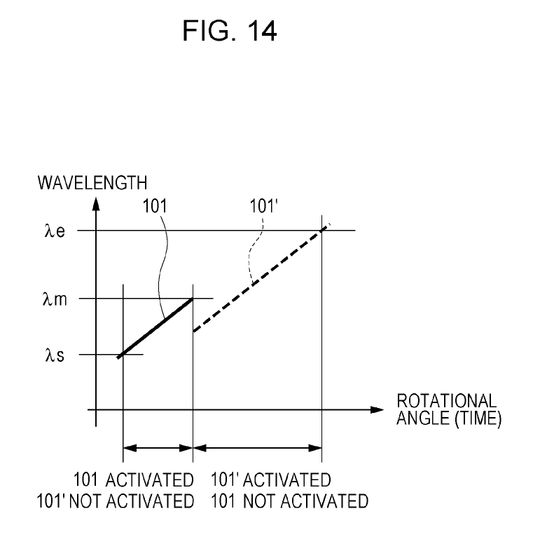

FIG. 14 is a graph showing the relationship between the rotational angle of the rotating disc 105 and the oscillation wavelength λ. Since Δθ>0, similar to the case illustrated in FIG. 10A according to the second embodiment, a switching time can be provided when the switching from the optical gain medium 101 to the optical gain medium 101′ is performed.

### Seventh Embodiment

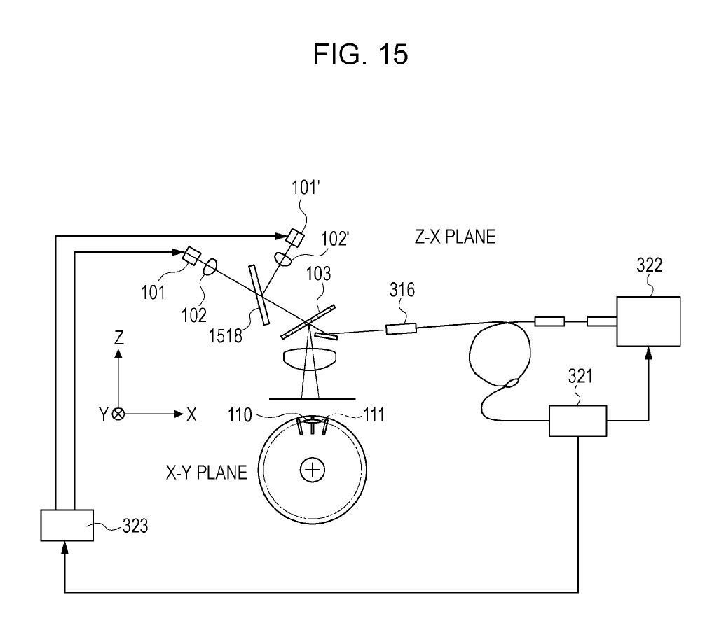

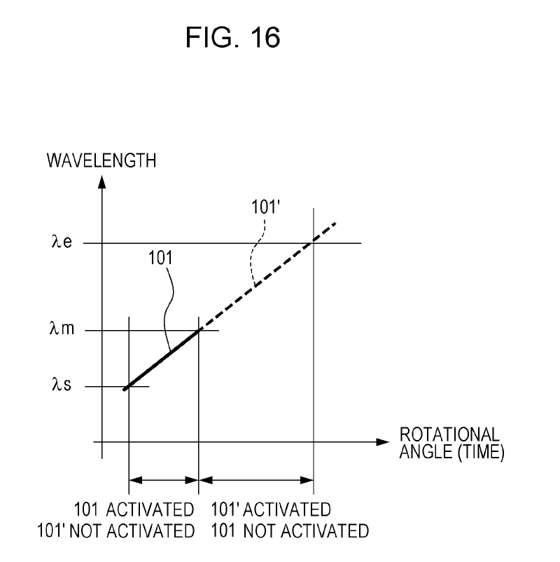

A seventh embodiment will be described with reference to FIGS. 15 and 16. The apparatus illustrated in FIG. 15 corresponds to the case in which Δθ=0 and ΔΦ=0 in FIGS. 8A and 8B.

Reference numeral 1518 denotes a half mirror or a polarization beam splitter that multiplexes and demultiplexes the oscillation light beams to and from the optical gain media 101 and 101′.

Thus, only one optical input coupler 316 is required and the optical multiplexer 317 included in, for example, the apparatus illustrated in FIG. 13 may be omitted. As a result, light utilization efficiency can be increased.

The light beams from the optical gain media 101 and 101′ overlap in the common gain wavelength range. Therefore, the wavelength detection unit 321 detects the wavelength, and the driving states of the optical gain media 101 and 101′ are switched on the basis of the result of the detection.

The light beams projected onto the rotating disc 105 overlap in a manner similar to that in the apparatus according to the sixth embodiment. Therefore, the restriction on the position of the rotation center of the rotating disc 105 can be reduced.

FIG. 16 is a graph showing the relationship between the rotational angle of the rotating disc 105 and the oscillation wavelength λ according to the present embodiment.

### Eighth Embodiment

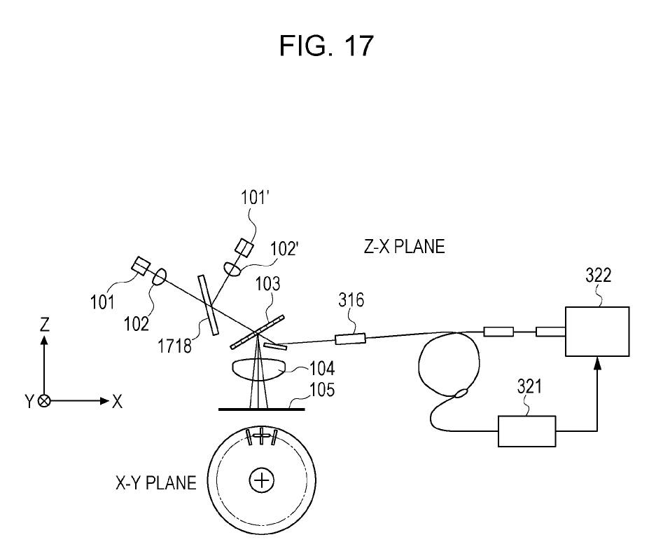

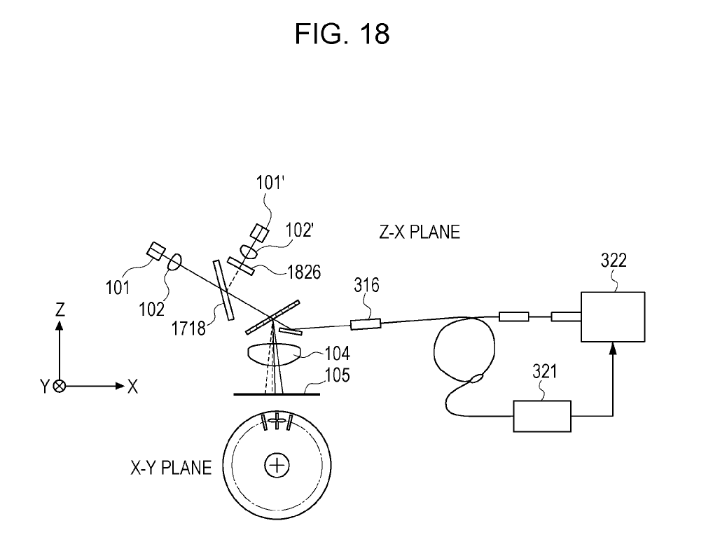

An eighth embodiment will be described with reference to FIGS. 17 and 18.

Similar to the apparatus illustrated in FIG. 15, the apparatus of the present embodiment corresponds to the case in which Δθ=0 and ΔΦ=0.

In the apparatus illustrated in FIG. 17, the component denoted by 1718 is a dichroic mirror 1718.

The overlapping gain wavelength bands of the optical gain media 101 and 101′ are separated from each other by the dichroic mirror 1718.

In the apparatus illustrated in FIG. 18, the overlapping gain wavelength bands of the optical gain media 101 and 101′ are separated from each other by an optical filter 1826.

In this apparatus, the component denoted by 1718 is a half mirror.

In the apparatuses illustrated in FIGS. 17 and 18, it is not necessary to perform the switching between the optical gain media 101 and 101′. Therefore, the structure of the wavelength sweeping light source can be simplified.

### Ninth Embodiment

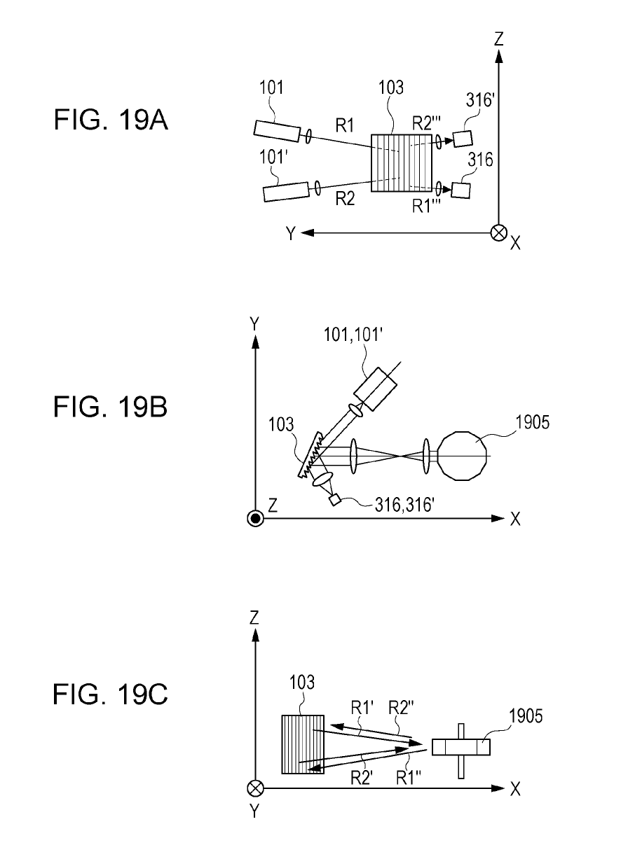

A device including a polygonal mirror according to a ninth embodiment will be described with reference to FIGS. 19A to 19C.

The apparatus illustrated in FIGS. 19A to 19C is an example of an apparatus including a movable strip-shaped member. FIG. 19A is a diagram illustrating the structure of FIG. 19B viewed in the direction from the negative side to the positive side of the X axis. FIG. 19C is a diagram illustrating the structure of FIG. 19B viewed in the direction from the negative side to the positive side of the Y axis.

The divergent light beam emitted from the optical gain medium 101 is collimated by a collimator, and is incident on the diffraction grating 103 such that the optical axis thereof is on a plane including one of the grooves of the diffraction grating 103 as light beam R1.

Then, the light beam R1 is angularly dispersed into light beams of different wavelengths, and a light beam R1′ of a certain wavelength is incident on a surface of a polygonal mirror 1905 and reflected by the polygonal mirror 1905. The reflected light beam R1″ is incident on the diffraction grating 103 again, returns to the optical gain medium 101 along the same direction as the direction of the light beam R1, and is reflected.

The wavelength is selected in accordance with the rotational angle of the polygonal mirror 1905, and wavelength sweeping is performed when the polygonal mirror 1905 is rotated.

The light beam from the optical gain medium 101′ and the light beam from the optical gain medium 101 are on the plane including one of the grooves of the diffraction grating 103 and are at an angle with respect to each other, as illustrated in FIGS. 9A to 9C. Similar to the first embodiment, the light beams are oscillated in the optical input couplers 316 and 316′ such that the gain wavelength bands of the optical gain media 101 and 101′ overlap.

Accordingly, a wavelength sweeping light source can be provided by driving the optical gain media 101 and 101′ so as to combine the oscillation wavelength bands by using a wavelength detection unit (not shown).

### Tenth Embodiment

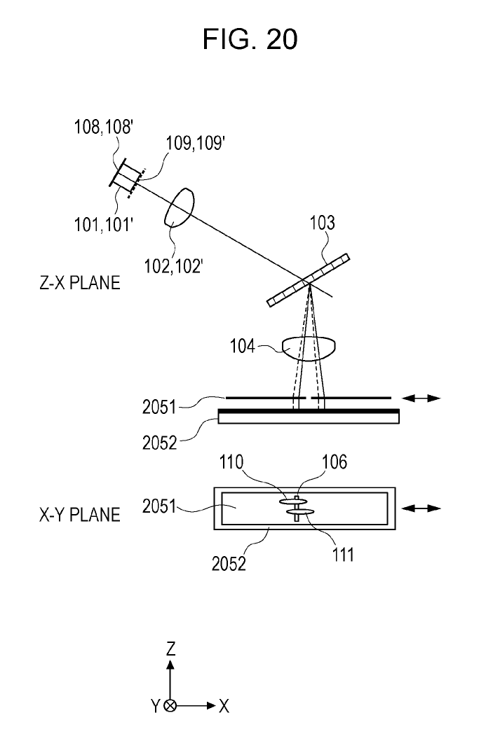

FIG. 20 illustrates a device including a wavelength selecting unit that includes a light blocking member 2051 and a mirror 2052 instead of the rotating disc 105 used in the above-described first embodiment.

A strip-shaped member 106, which is an opening, is formed in the light blocking member 2051. The light beam having a wavelength selected by the strip-shaped member 106 is reflected by the mirror 2052, amplified by the optical gain media 101 and 101′, and resonates between the mirror 2052 and the reflective films 108 and 108′.

Wavelength sweeping is performed by driving the light blocking member 2051 having the strip-shaped member 106 in the direction shown by the arrow in FIG. 20.

Similar to the first embodiment, an output from this light source device is obtained by using 0-order transmission light from the diffraction grating 103.

According to the present embodiment, the structure of the light source device can be simplified.

### Eleventh Embodiment

An optical coherence tomography (OCT) apparatus including a wavelength sweeping light source device according to an eleventh embodiment of the present invention will now be described.

In the OCT apparatus, one of two arms (measurement portion) receives light reflected by an inspection object that has a plurality of boundary surfaces in an optical axis direction, and the other arm (reference portion) receives light reflected by a reference surface. A modulated interfering signal is obtained by causing the received lights to interfere with each other and sweeping the wavelength of the light from the light source. Tomographic information is obtained as a result of Fourier transformation of the modulated interfering signal.

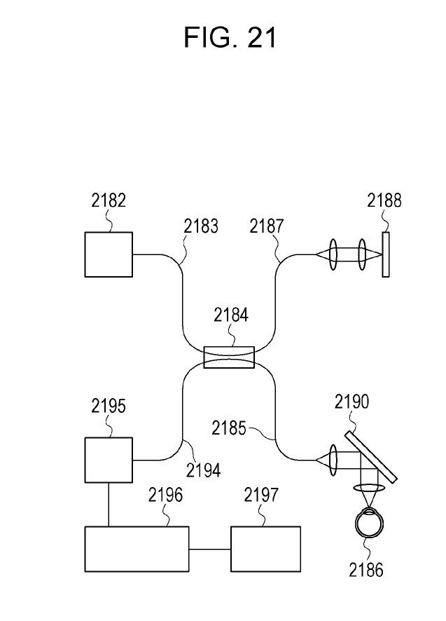

FIG. 21 is a schematic diagram illustrating the OCT apparatus according to the eleventh embodiment of the present invention.

Referring to FIG. 21, a light source unit 2182 includes a wavelength sweeping light source device according to an embodiment of the present invention. Reference numeral 2186 denotes a retina in a fundus of an eye, which is an inspection object.

A mirror 2190 is used to scan the fundus. The mirror 2190 and an optical fiber 2185 that transmits light reflected by the inspection object 2186 form an inspection-object measurement unit.

A reference mirror 2188 and an optical fiber 2187 that transmits light reflected by the reference mirror 2188 form a reference unit.

A fiber coupler 2184 forms an interference unit that multiplexes the reflected light (light beam) from the inspection-object measurement unit and the reflected light (light beam) from the reference unit.

A photoelectric conversion element 2195 serves as an optical detector that detects interference light (modulated interference signal) from the interference unit.

A computer 2196 serves as an image processing unit that converts the electrically detected signal into a digital signal and subjects the signal to data processing such as Fourier transformation to obtain a tomographic image of the inspection object.

Thus, a tomographic image is obtained on the basis of the light detected by the optical detector. A display 2197 visualizes the tomographic image.

A light beam emitted from the light source unit 2182 is guided through an optical fiber 2183 and is divided into two light beams by the fiber coupler 2184.

One of the two light beams passes through the optical fiber 2185 and is incident on the retina of the eye, which is the inspection object. The reflected light from the retina passes through the optical fiber 2185 again and returns to the fiber coupler 2184.

The other one of the two light beams passes through the optical fiber 2187 and is incident on the reference mirror 2188. The reflected light from the reference mirror 2188 passes through the optical fiber 2187 again and returns to the fiber coupler 2184.

The reflected light from the surface of the inspection object and the reflected light from the reference surface interfere with each other in the fiber coupler 2184. Then, the interference light passes through an optical fiber 2194 and is input to the photoelectric conversion element 2195.

When wavelength sweeping is performed so as to change the wavelength of the light emitted from the light source unit 2182, a modulated interference signal corresponding to a cross-sectional structure can be obtained as described above.

This signal is converted into a digital signal and is Fourier transformed by the computer 1196. As a result, a cross-section signal is obtained.

This cross-section signal corresponds to a point. Therefore, the mirror 2190 is scanned to measure the cross-section signal one dimensionally. The result of the measurement is visualized by the display 2197 as a tomographic image.

The light source unit 2182 included in the OCT apparatus according to the present embodiment includes a light source device according to an embodiment of the present invention. Since the light source device is capable of performing wavelength sweeping over a wide wavelength band, tomographic information having a high resolution in the depth direction can be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-162158 filed Jul. 25, 2011, which is hereby incorporated by reference herein in its entirety.

What is claimed is:

1. A light source device capable of varying a light oscillation wavelength, the light source device comprising:
a plurality of optical gain media that amplify light, the optical gain media having gain wavelength bands that partially overlap and different maximum gain wavelengths;
a dispersing element that is formed of a single element and on which each of light beams emitted from the optical gain media is incident, the dispersing element dispersing the light beams emitted from the optical gain media into light beams of different wavelengths; and
a wavelength selecting element that selects a light beam of a predetermined wavelength from the light beams of different wavelengths into which the light beams emitted from the optical gain media are dispersed by the dispersing element,
wherein the light source device emits the light beam of the predetermined wavelength selected by the wavelength selecting element.

2. The light source device according to claim 1, wherein the light source device successively emits a light beam in a certain wavelength band emitted from one of the optical gain media and a light beam in another wavelength band emitted from another one of the optical gain media.

3. The light source device according to claim 2, wherein the light source device emits the light beam in the certain wavelength band while performing wavelength sweeping, and emits the light beam in the another wavelength band while performing wavelength sweeping.

4. The light source device according to claim 1, wherein switching between the light beams of the respective wavelength bands is performed by electrical switching between the optical gain media.

5. The light source device according to claim 1, further comprising:
optical switches disposed in optical paths used to couple the light beams of the respective wavelength bands with an optical coupler,
wherein switching between the light beams of the respective wavelength bands is performed by using the optical switches.

6. The light source device according to claim 1, wherein the optical gain media are semiconductor optical amplifiers.

7. The light source device according to claim 1, wherein the dispersing element is a diffraction grating.

8. The light source device according to claim 7, wherein, when the optical gain media are denoted by M₁, M₂, . . . , Mₙ in order from the optical gain medium having the gain wavelength band at a short-wavelength side, and when angles of chief rays of the light beams emitted from the optical gain media M₁, M₂, . . . , Mₙ and incident on the diffraction grating with respect to a plane that includes a normal line of the diffraction grating and that is parallel to a direction of grooves in the diffraction grating are α₁, α₂, . . . , αₙ, respectively, where αₖ>αₖ₊₁ and k is a positive integer, the optical gain media M, M₂, . . . , Mₙ are arranged in an optical resonator including the wavelength selecting element so that angles between the chief rays Δθₙ (Δθ₁=α₁−α₂, Δθ₂=α₂−α₃, . . . , Δθₙ=αₙ−αₙ₊₁) satisfy Δθₙ (Δθ₁, Δθ₂, . . . , Δθₙ)≦0.

9. The light source device according to claim 7, wherein, when the optical gain media are denoted by M₁, M₂, . . . , Mₙ in order from the optical gain medium having the gain wavelength band at a short-wavelength side, and when angles of chief rays of the light beams emitted from the optical gain media M₁, M₂, . . . , Mₙ and incident on the diffraction grating with respect to a plane that includes a normal line of the diffraction grating and that is perpendicular to a direction of grooves in the diffraction grating are β₁, β₂, . . . , βₙ, respectively, where βₖ>βₖ₊₁ and k is a positive integer, the optical gain media M₁, M₂, . . . , Mₙ are arranged so that angles between the chief rays ΔΦₙ (ΔΦ₁=β₁−β₂, ΔΦ₂=β₂−β₃, . . . , ΔΦₙ=βₙ−βₙ₊₁) satisfy ΔΦₙ (ΔΦ₁, ΔΦ₂, . . . , ΔΦDₙ)≧0 or ΔΦₙ (ΔΦ₁, ΔΦ₂, . . . , ΔΦₙ)<0.

10. The light source device according to claim 1, wherein the wavelength selecting element includes a rotating body that reflects or transmits light.

11. The light source device according to claim 10, wherein the rotating body has a strip-shaped portion that reflects or transmits light.

12. The light source device according to claim 11, wherein the rotating body is a polygonal mirror.

13. The light source device according to claim 10, wherein the rotating body is disc-shaped.

14. The light source device according to claim 13, wherein the light beams of the respective wavelength bands that are emitted from the optical gain media and incident on the disc-shaped rotating body after passing through the diffraction grating are arranged next to each other in a radial direction of the disc-shaped rotating body.

15. An optical coherence tomography apparatus comprising:
a light source unit including the light source device according to claim 1;
an inspection-object measurement unit that irradiates an inspection object with light from the light source unit and transmits the reflected light from the inspection object;
a reference unit that irradiates a reference mirror with the light from the light source unit and transmits the reflected light from the reference mirror;
an interference unit that causes the reflected light from the inspection-object measurement unit and the reflected light from the reference unit to interfere with each other;
an optical detector that detects interference light output from the interference unit; and
an image processing unit that generates a tomographic image of the inspection object on the basis of the interference light detected by the optical detector.
